(19) United States
(12) Patent Application Publication
(10) Pub. No.: US 2005/0211416 A1
(43) Pub. Date: Sep. 29, 2005

(54) Heat sink with fins and a method for manufacturing the same

(76) Inventors: Kenya Kawabata, Tokyo (JP); Noboru Matsuki, Tokyo (JP); Eiji Hanawa, Tokyo (JP); Hajime Noda, Tokyo (JP); Ryoji Ohno, Tokyo (JP); Yuichi Kimura, Tokyo (JP)

Correspondence Address: CANTOR COLBURN, LLP, 55 GRIFFIN ROAD SOUTH, BLOOMFIELD, CT, 06002, US

(21) Appl. No.: 10/966,719

(22) Filed: Oct. 15, 2004

Related U.S. Application Data
(60) Provisional application No. 60/512,403, filed on Oct. 17, 2003.

(51) Int. Cl. H05K 7/20

(52) U.S. Cl. 165/80.3; 361/704

(57) ABSTRACT

A heat sink with fins comprising a pillar-shaped base member, and a plurality of fins which are inserted into a plurality of grooves formed in the side face of said base member and then both sides of each of said grooves are plastic-deformed to joint said fins in said base member.

### FIELD OF THE INVENTION

The present invention relates to a heat sink with fins in which the fins are fixed in the side face of a pillar-shaped base member and a method for manufacturing the same.

### RELATED ART

The amount of heat generation and heat density in CPU, devices and the like remarkably increases, and a high performance of heat sink excellent in heat dissipating efficiency is needed. Conventionally, a heat sink manufactured by aluminum extrusion is widely used, since the manufacturing cost thereof is low. According to the heat sink by the aluminum extrusion, since the base member and the fins are integrally formed, i.e., as a one piece component, it is easy to manufacture. However, due to the manufacturing method, it is technically limited to reduce a pitch between the adjacent fins so that the fins with fine pitch are not formed. Furthermore, the height of the fins is also technically limited due to the manufacturing method so that tall fins are not formed.

Japanese Patent Application Publication No. 2000-31354 discloses a conventional heat sink. The conventional heat sink is a plate-fin type heat sink, and integrally formed by extrusion. The heat sink comprises a plurality of heat dissipating plate-fins and the base plate integrally formed. A large number of pate-fins are formed at regular intervals and in perpendicular to the base plate. The heat sink is manufactured by extrusion of aluminum or aluminum alloy, as described above.

However, in the conventional heat sink, as described above, since the base plate and the heat dissipating fins are integrally formed, it is easy to manufacture, but it is technically difficult to form the fins with fine pitch on the base plate, due to the limited pitch in the manufacturing method. Furthermore, the height of the fins is limited according to the manufacturing method, it is technically difficult to form tall fins on the base plate. Therefore, there is a problem in which the heat generating component generating large amount of heat and having high heat generating density is not effectively cooled, since the heat dissipating efficiency thereof is poor.

Furthermore, since the heat sink by aluminum extrusion having a prescribed efficiency can be made at low cost, a substantially cubicle heat sink as a whole with fins cut off at appropriate length after extrusion is formed, and a fan is installed on the upper face portion or side face portion of thus formed heat sink which is cooled by forced convection of the air flow.

However, there is a problem in the above heat sink that the air flow from the fan can not be made fully use of in the cubicle shape, when the required efficiency becomes higher.

### SUMMARY OF THE INVENTION

The first embodiment of the heat sink with fins of the invention is a heat sink with fins comprising a pillar-shaped base member, and a plurality of fins which are inserted into a plurality of grooves formed in a side face of said base member and then both sides of each of said grooves are plastic-deformed to joint said fins in said base member.

In the second embodiment of the heat sink with fins of the invention, said fin comprises a flat plate fin, and a plurality of said fins are inserted into each of said grooves.

In the third embodiment of the heat sink with fins of the invention, said pillar-shaped base member comprises a truncated cone-shaped base member.

In the fourth embodiment of the heat sink with fins of the invention, said pillar-shaped base member comprises a cylindrical base member.

In the fifth embodiment of the heat sink with fins of the invention, said pillar-shaped base member comprises a polygonal pillar-shaped base member.

In the sixth embodiment of the heat sink with fins of the invention, said pillar-shaped base member comprises a pipe-shaped base member.

In the seventh embodiment of the heat sink with fins of the invention, each of said grooves is formed to be inclined so as to have a specific angle to a longitudinal axis of said base member.

In the eighth embodiment of the heat sink with fins of the invention, each of said grooves is formed to be inclined so as to have a specific angle to a respective normal line on a surface of said base member.

In the ninth embodiment of the heat sink with fins of the invention, at least one slit is formed in a portion of said base member along an axis direction thereof.

In the tenth embodiment of the heat sink with fins of the invention, the heat sink with fins further comprises a cover portion to cover at least part of an outer peripheral portion formed by connecting outer side ends of respective said plurality of fins jointed in said base member.

In the eleventh embodiment of the heat sink with fins of the invention, at least a part of a central portion of said base member is cut out along a longitudinal axis thereof.

The first embodiment of the method for manufacturing a heat sink with fins comprises the steps of:
preparing a pillar-shaped (ex. truncated cone-shape, cylindrical shape, pipe-shape and polygonal shape) base member and a plurality of fins;
forming a plurality of grooves in the side face of said base member, each of which has a prescribed constant angle (including 0 degree) to a respective normal lines in the surface of the base member;
inserting the plurality of fins into the respective grooves; and
plastic-deforming respective portions of the surface of the base member to joint the fins to the base member.

The second embodiment of the method for manufacturing a heat sink with fins comprises the steps of:
preparing a pillar-shaped (ex. truncated cone-shape, cylindrical shape, pipe-shape and polygonal shape) base member and a plurality of fins;
forming a plurality of grooves in the side face of said base member;
inserting the plurality of fins into the respective grooves;
plastic-deforming respective side portions of the fins in the surface of the base member by moving a pressing jig toward an axis of the base member to joint the fins to the base member; and
moving the pressing jig away from the axis of the base member.

The third embodiment of the method for manufacturing a heat sink with fins comprises the steps of:
preparing a pillar-shaped (ex. truncated cone-shape, cylindrical shape, pipe-shape and polygonal shape) base member in which a part of a central portion is cut out along a longitudinal axis thereof and a plurality of fins;
forming a plurality of grooves in the side face of said base member;
inserting the plurality of fins into the respective grooves;
placing a deform-preventing jig in a respective space between fins;
inserting a pressing jig in the cutout central portion; and
expanding the pressing jig outwardly to deform the base member to joint the fins to the base member.

In the fourth embodiment of the method for manufacturing a heat sink with fins, said pressing jig is inserted through a sheet in the cutout central portion.

In the fifth embodiment of the method for manufacturing a heat sink with fins, said deform-preventing jig is fixed on the base member when pressed, and said deform-preventing jig is released after finishing the pressing.

In the sixth embodiment of the method for manufacturing a heat sink with fins, said pressing jig inserted in the cutout central portion changes in an outer diameter to deform the base member.

The seventh embodiment of the method for manufacturing a heat sink with fins comprises the steps of:
preparing a truncated cone-shaped base member and a plurality of fins;
forming a plurality of grooves in the side face of said base member;
inserting the plurality of fins into the respective grooves;
plastic-deforming respective side portions of the fins in the surface of the base member by moving a pressing jig having a stepped cutting portion in parallel to an axis of the base member to joint the fins to the base member.

### BRIEF DESCRIPTION OF THE DRAWINGS

FIG. 1-(a) is a schematic oblique view showing one embodiment of the heat sink with fins of the invention, FIG. 1-(b) is a partially enlarged view to explain the heat sink with fins of the invention;

FIG. 2-(a) is a partial cross sectional view showing fins of the heat sink with fins of the invention, FIG. 2-(b) is a partial cross sectional view to explain the fins in FIG. 2-(a);

FIG. 3 is a cross sectional view showing other embodiment of the heat sink with fins of the invention;

FIG. 4 is a view to explain a method for fixing the fins in the heat sink with fins of the invention;

FIG. 5 is a view to explain another method for fixing the fins in the heat sink with fins of the invention;

FIG. 6 is a schematic oblique view showing one embodiment of the heat sink with fins of the invention;

FIG. 7-(a) is a schematic oblique view showing one embodiment of the heat sink with fins of the invention in which a whole side portion thereof is covered by a cover, FIG. 7-(b) is a schematic oblique view showing one embodiment of the heat sink with fins of the invention in which a part of the side portion thereof is covered by a cover;

FIG. 8-(a) is a cross sectional view explaining one embodiment of the heat sink with fins of the invention in which a part of a central portion of the base member is cut out, FIG. 8-(b) is a cross sectional view explaining other embodiment of the heat sink with fins of the invention in which a whole of the central portion of the base member is cut out;

FIG. 9-(a) is a view showing other method for fixing the fins in the heat sink with fins of the invention, FIG. 9-(b) is a view explaining the portion in which the fin is fixed to the base member;

FIGS. 10-(a) to 10-(c) are views explaining one embodiment of the method for manufacturing a heat sink with fins of the invention;

FIGS. 11-(a) to 11-(c) are views explaining other embodiment of the method for manufacturing a heat sink with fins of the invention;

FIG. 12 is a view explaining other embodiment of the method for manufacturing a heat sink with fins of the invention;

FIG. 13-(a) and 13-(b) are views explaining other embodiment of the method for manufacturing a heat sink with fins of the invention;

FIG. 14-(a) and 14-(b) are views explaining other embodiment of the method for manufacturing a heat sink with fins of the invention;

FIG. 15-(a) to 15-(d) are views explaining other embodiment of the method for manufacturing a heat sink with fins of the invention;

FIG. 16 is a view showing one embodiment of the heat sink with fins of the invention;

FIG. 17 is a view explaining the grooves formed in the truncated cone-shaped base member of the invention;

FIG. 18-(a) and 18-(b) are views explaining other embodiment of the method for manufacturing a heat sink with fins of the invention; and

FIG. 19-(a) is a view explaining the portion in which a fan is arranged on the cylindrical base member of the invention, FIG. 19-(b) is a view explaining the portion in which a fan is arranged on the truncated cone-shaped base member of the invention.

### DETAILED DESCRIPTON OF THE INVENITION

The heat sink with fins of the invention and the method for manufacturing the same are explained with reference to the drawings.

One embodiment of the heat sink with fins of the invention comprises a pillar-shaped base member, and a plurality of fins which are inserted into a plurality of grooves formed in the side face of said base member and then both sides of each of said grooves are plastic-deformed to joint said fins in said base member. The above-mentioned pillar-shaped base member may be one of a truncated cone-shaped base member, a cylindrical base member, a polygonal pillar-shaped base member, and a pipe-shaped base member.

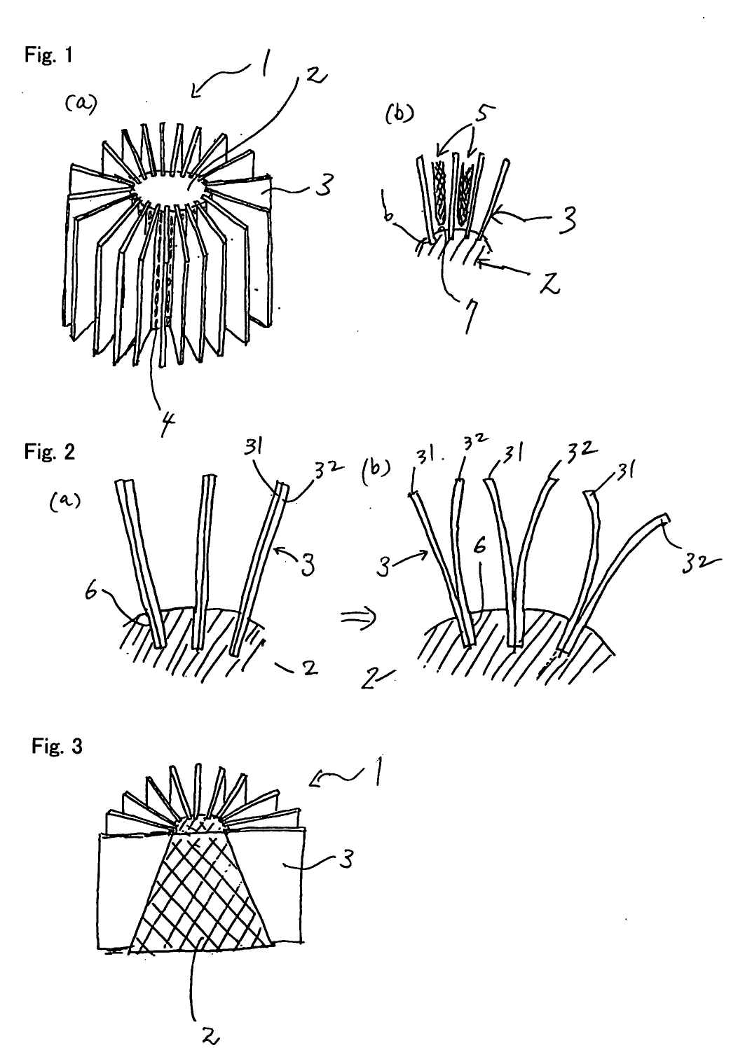

FIG. 1-(a) is a schematic oblique view showing one embodiment of the heat sink with fins of the invention, and FIG. 1-(b) is a partially enlarged view to explain the heat sink with fins of the invention. As shown in FIG. 1-(a), the heat sink with fins of the invention comprises a pillar-shaped base member 2, and a plurality of fins 3 which are inserted into a plurality of grooves formed in a side face of the base member and then both sides of each of the grooves are plastic-deformed to joint the fins in the base member. More specifically, as shown in FIG. 1-(b), a plurality of grooves 6 are formed in a side face of the cylindrical base member 2. The fin 3 is inserted into each of thus formed grooves 6, and a surface portion 7 between adjacent fins (i.e., both sides of each of the grooves) are pressed by a pressing jig 5 to plastic-deform the surface portions of the base member to joint the fins to the surface portion of the base member. The plastic deformation may be made discontinuously in the surface portion between the adjacent fins as shown in FIG. 1-(a) by the reference numeral 4, or made continuously.

FIG. 2-(a) is a partial cross sectional view showing fins of the heat sink with fins of the invention, and FIG. 2-(b) is a partial cross sectional view to explain the fins in FIG. 2-(a). As shown in FIG. 2-(a), a plurality of fins (3) are inserted into each of the plurality of grooves (6) formed in the side face of the base member (2). In the drawing, there is shown an example in which two fins are inserted into each of the grooves. The material of the fins may be the same, or the different from each other, for example, fins made of copper and aluminum. Two fins are inserted into each groove formed in the surface portion of the base member, and the surface portions of the base member between the adjacent fins are plastic-deformed to joint the fins to the base member. Then, the tip portions (31,32) of the two fins (3) are bent outwardly to be spaced, as shown in FIG. 2-(b).

Since a plurality of fins are inserted into one groove, jointed to the base member, and the tip portions thereof are bent outwardly to be spaced, the density of the fins becomes higher and the heat dissipating area are enlarged to improve the heat dissipating efficiency. Furthermore, since the fins are bent to a prescribed shape, a resistance of the air passing through the fins is made smaller to improve the heat dissipating efficiency.

The above-mentioned method for fixing the fins to the base member can be employed to all types (shapes) of the base member.

FIG. 3 is a schematic cross sectional view showing other embodiment of the heat sink with fins of the invention. The heat sink 1 with fins of this embodiment comprises a truncated cone-shaped base member 2, and a plurality of fins 3 which are inserted into a plurality of grooves formed in a side face of the base member and then both sides of each of the grooves are plastic-deformed to joint the fins in the base member. The base member comprises a truncated cone-shaped base member, as shown in FIG. 3. The fin 3 has a shape corresponding to a slope of the surface portion of the truncated cone-shaped base member. More specifically, the width of the fin becomes narrow from one end toward the other end in an example as shown in FIG. 3.

A plurality of grooves formed in the side face of the truncated cone-shaped base member have approximately the same depths, and the fins are inserted therein. After the fins are inserted, the surface portions of base member between the fins are pressed by the pressing jig to be plastic-deformed so that the fins are mechanically crimped in the side face of the base member to joint the fins to the base member. The truncated cone-shaped base member has a large contact area with a cooled component such as a CPU. Furthermore, each of the heat dissipating fins has a large area in the upper portion thereof which is located near the fan.

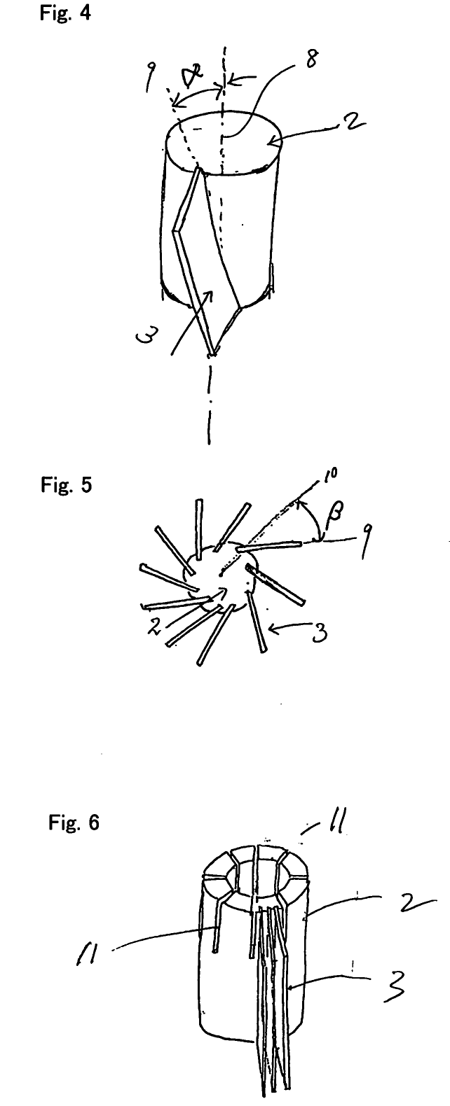

FIG. 4 is a view to explain a method for fixing the fins in the heat sink with fins of the invention. In the heat sink with fins of this embodiment, the fins are jointed in the side face of the base member in such manner that fins are not parallel to the axis direction of the base member but inclined with a specific angle to the axis of the base member. In the example as shown in FIG. 4, the fin 3 is arranged and jointed to the base member with an angle of a to the axis direction 8 of the base member 2. The fin has width in corresponding to a shape of the side surface portion of the base member so that both ends of the fin have a larger width than that of the center portion thereof. According to this embodiment in which the inclined fins are jointed to the base member, the resistance of the air passing through the fins from the fan installed to the upper portion of the base member becomes smaller to improve the heat dissipating efficiency.

FIG. 5 is a view to explain another method for fixing the fins in the heat sink with fins of the invention. In the heat sink with fins of this embodiment, the plurality of fins 3 are arranged and jointed in the side face of the base member in such manner that fins are inclined with a constant specific angle (β) to the respective normal lines 10 in the fin-fixing portions on the side surface of the base member. According to thus arranged fins, the height of the fin portion of the heat sink may become small. Furthermore, as described later, the fixed fins may be further bent so as to expand the scope of uses of the heat sink.

FIG. 6 is a schematic oblique view showing one embodiment of the heat sink with fins of the invention. In this embodiment of the heat sink with fins, a plurality of slits 11 are provided with the pipe-shaped base member 2 or the base member in which a part of a central portion of the cylindrical base member 2 is cut out along a longitudinal axis thereof. The fins are arranged and jointed in the same manner as that in other embodiments. More specifically, a plurality of grooves are formed in the side face of the above-mentioned base member 2, the plurality of fins are inserted into thus formed respective grooves, and respective side portions of the fins in the side face of the base member are plastic-deformed by pressing a pressing jig to joint the fins to the base member. By the formation of the slits, the air flow by the fan is changed to improve heat dissipating efficiency. In particular, the air flow becomes effectively smooth to the central portion of the base member in which a part of the central portion of the cylindrical base member is cut out along a longitudinal axis thereof, thus effectively dissipating the heat transferred to the bottom portion of the base member from the component to be cooled.

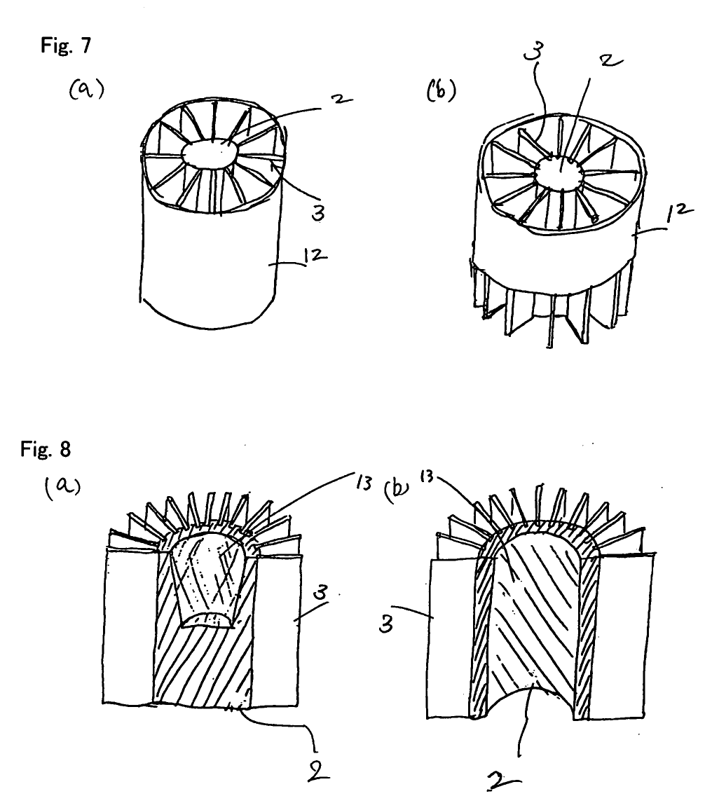

FIG. 7-(a) is a schematic oblique view showing one embodiment of the heat sink with fins of the invention in which a whole side portion thereof is covered by a cover. FIG. 7-(b) is a schematic oblique view showing one embodiment of the heat sink with fins of the invention in which a part of the side portion thereof is covered by a cover. As shown in FIG. 7-(a), a whole side portion of the heat sink 1 with fins of the invention is covered by the cover 12, which comprises the cylindrical base member 2 and a plurality of fins 3 which are inserted into the respective grooves formed in the side face of the cylindrical base member and plastic-deformed in both sides of the respective grooves to joint the fins to the base member.

Furthermore, as shown in FIG. 7-(b), a part of the side portion of the heat sink 1 with fins of the invention is covered by the cover 12, which comprises the cylindrical base member 2 and a plurality of fins 3 which are inserted into the respective grooves formed in the side face of the cylindrical base member and plastic-deformed in both sides of the respective grooves to joint the fins to the base member. According to the fact that at least the part of the side portion of the heat sink is covered by the cover, the air flow from the fan installed in the upper portion of the heat sink may be controlled so as to improve heat dissipating efficiency.

FIG. 8-(a) is a cross sectional view explaining one embodiment of the heat sink with fins of the invention in which a part of a central portion of the base member is cut out. FIG. 8-(b) is a cross sectional view explaining other embodiment of the heat sink with fins of the invention in which a whole of the central portion of the base member is cut out. As shown in FIG. 8-(a), a part of a central portion of the base member 2 of the heat sink 1 with fins is cut out to form a hollow portion 13, which heat sink comprises the cylindrical base member 2 and a plurality of fins 3 which are inserted into the respective grooves formed in the side face of the cylindrical base member and plastic-deformed in both sides of the respective grooves to joint the fins to the base member.

In this embodiment of the heat sink with fins, the heat transferred to the base member from the component to be cooled which is thermally connected to the bottom portion of the base member is dissipated by the air flown to the side face and the bottom face of the hollow portion from the fan, thus further improving heat dissipating efficiency. As shown in FIG. 8-(b), a whole of a central portion of the base member 2 of the heat sink 1 with fins is cut out to form a hollow portion 13, which heat sink comprises the cylindrical base member 2 and a plurality of fins 3 which are inserted into the respective grooves formed in the side face of the cylindrical base member and plastic-deformed in both sides of the respective grooves to joint the fins to the base member.

In this embodiment of the heat sink with fins, for example, a metal member of the size corresponding to the size of the hollow portion is to be inserted in the hollow portion to the bottom face, as described below. As a result, the heat transferred to the base member from the component to be cooled which is thermally connected to the bottom portion of the base member is dissipated by the air flown to the side face and the bottom face of the hollow portion from the fan, thus further improving heat dissipating efficiency. Furthermore, another member is incorporated in the hollow portion to be used for a plat form to fix the fan.

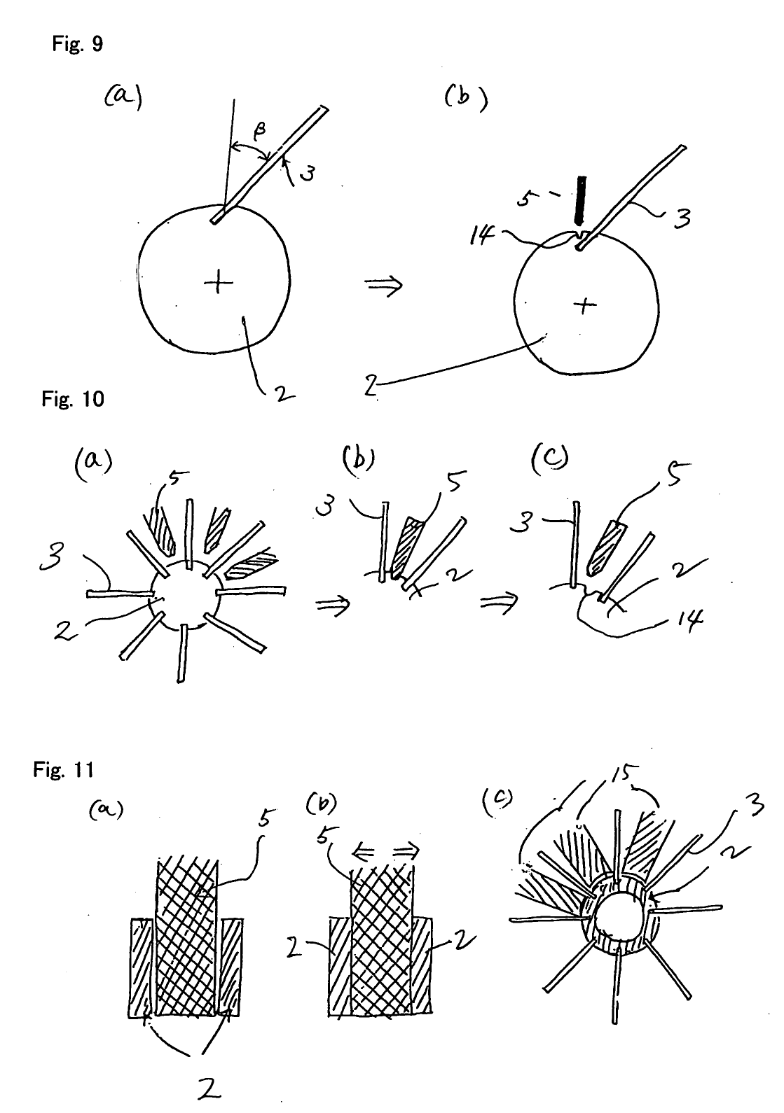

FIG. 9-(a) is a view showing other method for fixing the fins in the heat sink with fins of the invention. FIG. 9-(b) is a view explaining the portion in which the fin as shown in FIG. 9-(a) is fixed to the base member. More specifically, FIGS. 9-(a) and 9-(b) are views explaining the method for fixing the fins in the heat sink which is explained with reference to FIG. 5. The embodiment of the method for manufacturing the heat sink with fins of the invention is the method for manufacturing a heat sink with fins comprises the steps of: preparing a pillar-shaped base member (i.d., cylindrical, pipe-shaped, truncated cone-shaped, or polygonal base member) and a plurality of fins; forming a plurality of grooves in the side face of the base member, each of which has a prescribed constant angle to a respective normal lines in the surface of the base member; inserting the plurality of fins into the respective grooves; and plastic-deforming respective portions of the surface of the base member forming angle to the fins to joint the fins to the base member.

More specifically, as shown in FIG. 9-(a), each of the plurality of fins 3 is inserted in the respective grooves formed in the side face of the base member, each of which grooves has a prescribed constant angle (β) to a respective normal lines in the fin-fixing portion of the base member 2. Then, the respective portions of the surface of the base member forming angle to the fins are plastic-deformed to mechanically crimp the fins to the base member. Due to the fixing method of fins to the base member, the height of the fin portion of the heat sink may become small. Furthermore, as described later, the thus fixed fins may be further bent so as to expand the usages of the heat sink.

FIGS. 10-(a) to 10-(c) are views explaining one embodiment of the method for manufacturing a heat sink with fins of the invention. The embodiment of the method for manufacturing the heat sink with fins of the invention is the method for manufacturing a heat sink with fins comprises the steps of: preparing a pillar-shaped base member and a plurality of fins; forming a plurality of grooves in the side face of the base member; inserting the plurality of fins into the respective grooves; plastic-deforming respective side portions of the fins in the surface of the base member by moving a pressing jig toward an axis of the base member to joint the fins to the base member; and moving the pressing jig away from the axis of the base member.

More specifically, as shown in FIG. 10-(a), the plurality of grooves are formed in the side face of the cylindrical base member 2, and the fins 3 are inserted in the respective grooves. Then, as shown in FIG. 10-(b), the respective side portions of the fins in the surface of the base member are plastic-deformed by moving the set of pressing jigs 5 which are arranged between the adjacent fins toward an axis of the base member to joint the fins 3 to the base member 2. Then, as shown in FIG. 10-(c), the pressing jigs 5 are moved away from the plastic-deformed side portions 14 between the fins 3 in a direction away from the axis of the base member.

FIGS. 11-(a) to 11-(c) are views explaining other embodiment of the method for manufacturing a heat sink with fins of the invention. The embodiment of the method for manufacturing the heat sink with fins of the invention is the method for manufacturing a heat sink with fins comprises the steps of: preparing a pillar-shaped base member in which a part of a central portion is cut out along a longitudinal axis thereof and a plurality of fins; forming a plurality of grooves in the side face of said base member; inserting the plurality of fins into the respective grooves; placing a deform-preventing jig in a respective space between fins; inserting a pressing jig in the cutout central portion; and expanding the pressing jig outwardly to deform the base member to joint the fins to the base member.

More specifically, as shown in FIG. 11-(a), the pressing jig 5 is inserted in the pillar-shaped base member 2 in which at least part of the central portion is cut out along the longitudinal axis thereof. As shown in FIG. 11-(b), the outer diameter of the pressing jig 5 inserted into the cut out central portion of the base member is varied. More specifically, the pressing jig is inserted into the cut out central portion of the base member and expanded outwardly to deform the base member as shown by an arrow in the figure. In addition, as shown in FIG. 1-(c), a deform-preventing jig 15 is placed in the outer peripheral portion of the base member 2. The deform-preventing jig placed between the fins is fixed on the base member when the pressing jig is expanded (i.e., pressed) to joint the fins to the base member, and the deform-preventing jig is released after finishing the pressing.

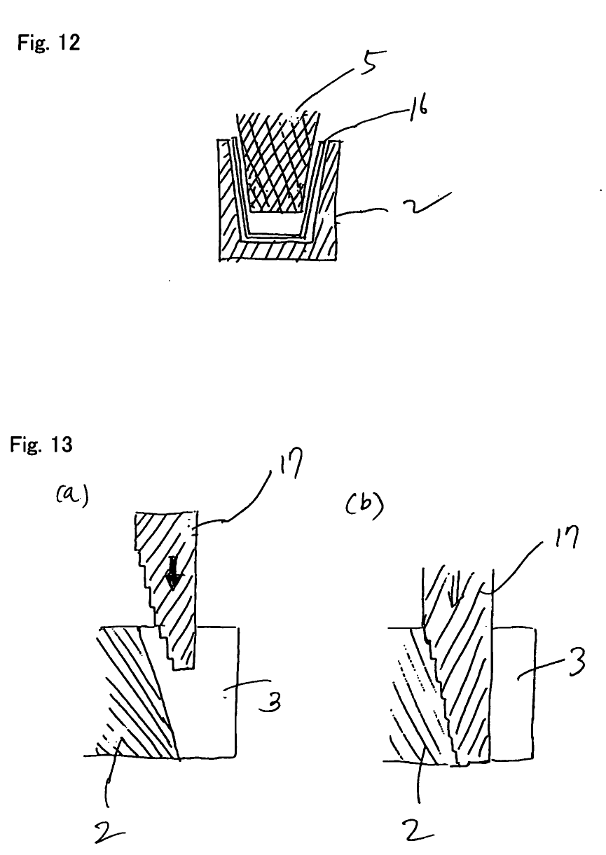

FIG. 12 is a view explaining other embodiment of the method for manufacturing a heat sink with fins of the invention. In the method for manufacturing a heat sink with fins of this embodiment comprising the steps of: preparing a pillar-shaped base member in which at least part of a central portion is cut out along a longitudinal axis thereof and a plurality of fins; forming a plurality of grooves in the side face of said base member; inserting the plurality of fins into the respective grooves; placing a deform-preventing jig in a respective space between fins; inserting a pressing jig in the cut out central portion; and expanding the pressing jig outwardly to deform the base member to joint the fins to the base member, the pressing jig is inserted through a sheet in the cut out central portion. More specifically, when the pressing jig 5 is inserted into the cut out central portion of the base member and expanded outwardly to joint the fins to the base member, the pressing jig 5 is inserted through a sheet 16 in the cutout central portion. This makes easy the removal of the pressing jig after finishing the pressing.

FIGS. 13-(a) and 13-b B are views explaining other embodiment of the method for manufacturing a heat sink with fins of the invention. As shown in FIG. 13-(a), the plurality of fins 3 are inserted into the respective grooves formed in the side surface of the truncated cone-shaped base member 2 having a trapezoidal vertical cross section. The respective side portions of the fins inserted in the grooves are pressed by a pressing jig having a tapering stepped cutting portion corresponding to the slope of the outer peripheral surface. As shown in FIG. 13-B, the pressing jig having a tapering stepped cutting portion presses and plastic-deforms the side portions between the fins inserted in the grooves to joint the plurality of fins to the base member.

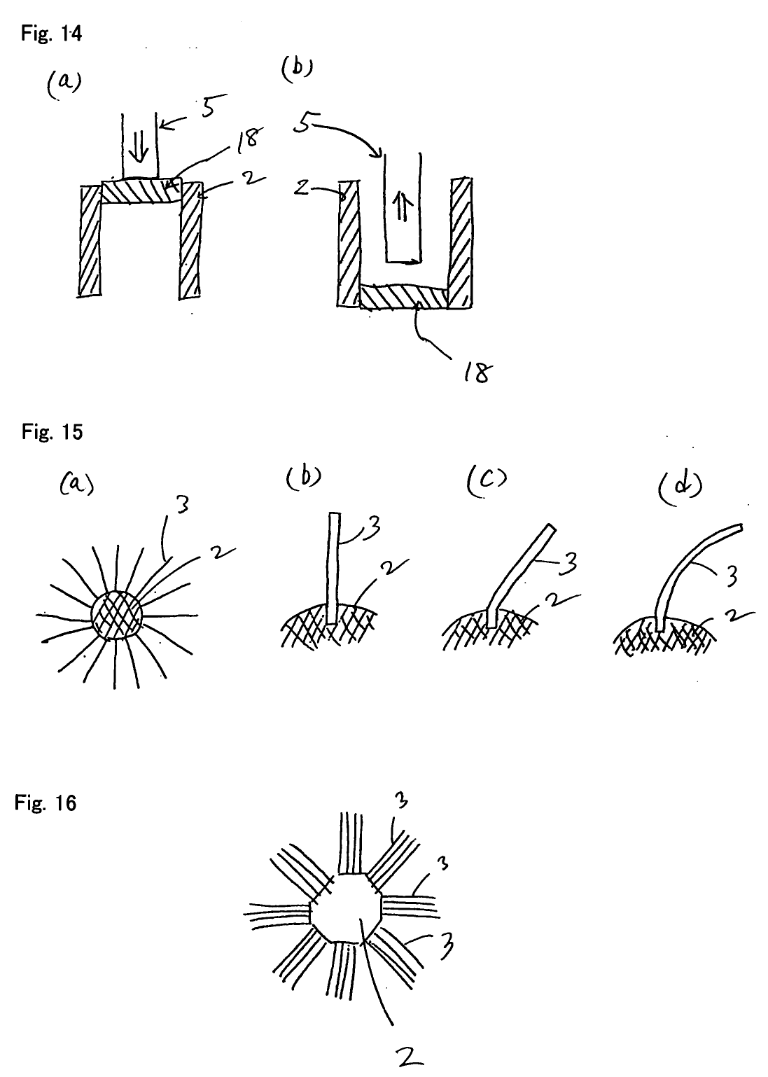

FIGS. 14-(a) and 14-(b) are views explaining other embodiment of the method for manufacturing a heat sink with fins of the invention. This embodiment of the method is the method for manufacturing a heat sink with fins comprises the steps of: preparing a pillar-shaped base member in which a whole of a central portion is cut out along a longitudinal axis thereof and a plurality of fins; forming a plurality of grooves in the side face of said base member; inserting the plurality of fins into the respective grooves; placing a deform-preventing jig in a respective space between fins; inserting a pressing jig in the cut out central portion; and expanding the pressing jig outwardly to deform the base member to joint the fins to the base member.

More specifically, a block for expanding the base member is placed in the central portion of the base member, and then the block is moved down toward the bottom face portion of the base member, thus deforming the base member from inner side thereof to joint the fins to the base member. The block for expanding the base member which reaches to the bottom face of the base member remains there as fixed so as to form a portion of the base member. In other words, as shown in FIG. 14-(a), the block 18 is placed on the upper face of a pipe-shaped base member 2, and moved down by the pressing jig 5 as shown by an arrow in the figure. This downward movement of the block deforms the base member from the inner side thereof as described above to joint the fins to the base member 2. As shown in FIG. 14-(b), the block 18 which reaches to the bottom face portion remains there as fixed to become a part of the base member. Then, the pressing jig 5 is moved and removed as shown by an arrow in the figure.

FIGS. 15-(a) to 15-(d) are views explaining other embodiment of the method for manufacturing a heat sink with fins of the invention. The method for manufacturing the heat sink with fins of this embodiment is as shown in FIG. 15-(a) and the method for manufacturing a heat sink with fins comprises the steps of: preparing a pillar-shaped base member 2 and a plurality of fins 3; forming a plurality of grooves in the side face of said base member; inserting the plurality of fins into the respective grooves; plastic-deforming respective side portions of the fins in the surface of the base member by moving a pressing jig toward an axis of the base member to joint the fins to the base member. The fins jointed to the base member by the plastic-deformation are folded by a prescribed angle from the jointed surface, or bent to form a curved face, as shown in FIGS. 15-(c) and 15-(d). Thus, the correlation between the air flow from the fan and the configuration of the fins may be optimized.

FIG. 16 is a view showing one embodiment of the heat sink with fins of the invention. More specifically, it shows the heat sink with fins of the invention comprising a polygonal pillar-shaped base member, and a plurality of fins which are inserted into a plurality of grooves formed in the side faces of the polygonal base member and then both sides of each of the grooves are plastic-deformed to joint the fins in the base member. The polygonal pillar-shaped base member may be a hexagonal pillar-shaped base member or an octagonal pillar-shaped base member. The fins may be radially arranged 360 degrees on all the side faces of the base member. The fins may be made of the same metal or different kind of metal, for example the combination of copper and aluminum fins.

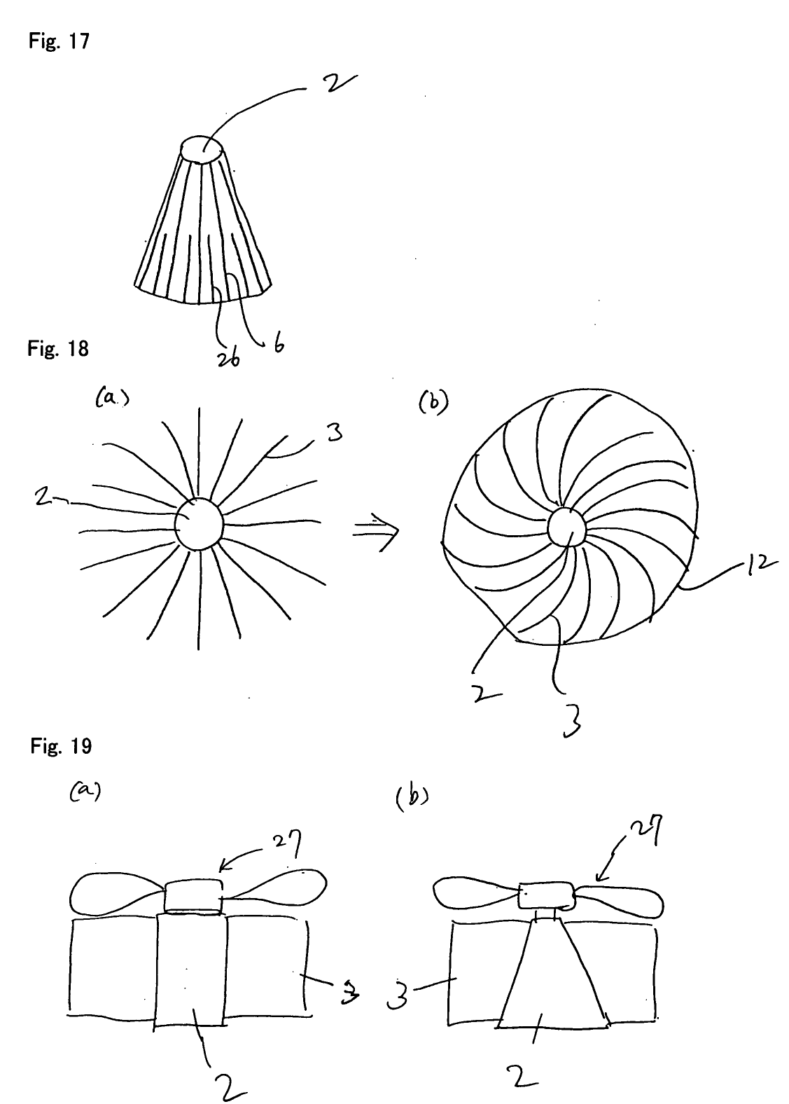

FIG. 17 is a view explaining the grooves formed in the truncated cone-shaped base member of the invention. More specifically, it shows the heat sink with fins of the invention comprising a truncated cone-shaped base member having a trapezoidal vertical cross section, and a plurality of fins which are inserted into a plurality of grooves formed in the side face of the truncated cone-shaped base member and then both sides of each of the grooves are plastic-deformed to joint the fins in the base member. As shown in FIG. 17, the grooves formed on the side surface of the truncated cone-shaped base member 2 comprise long grooves 6 formed across on the whole of the side surface of the truncated cone and short grooves 26 formed on the lower half portion between the long grooves. When different kinds of grooves are formed in the side face of the base member, it is possible to install fins in high density, thus further improving the heat dissipating efficiency.

FIGS. 18-(a) and 18-(b) are views explaining other embodiment of the method for manufacturing a heat sink with fins of the invention. The heat sink with fins of this embodiment comprises a combination of the heat sink with fins explained with reference to FIG. 15 and the heat sink with fins explained with reference to FIG. 7. More specifically, as shown in FIG. 18, the heat sink with fins of the invention comprises a cylindrical base member 2 and a plurality of fins 3 which are inserted into a plurality of grooves formed in the side face of the cylindrical base member and then both sides of each of the grooves are plastic-deformed to joint the fins in the base member.

In the heat sink with fins of this embodiment, the length of the fins is taller than that of the fins explained with reference to FIG. 1 so that the fins can be bent in spiral manner. Thus formed heat sink with fins is received within the cover 12 while the fins are bent in spiral manner, as shown in FIG. 15-(d). More specifically, the heat sink with the relatively taller fins bent in spiral manner is inserted and received in the tube-shaped cover, while turning the heat sink. Due to the feature of this embodiment, it is possible to obtain a heat sink having prescribed fins installed in high density within the tube-shaped cover.

FIG. 19-(a) is a view explaining the portion in which a fan is arranged on the cylindrical base member of the invention. FIG. 19-(b) is a view explaining the portion in which a fan is arranged on the truncated cone-shaped base member having a trapezoidal vertical cross section of the invention. As explained with reference to FIGS. 8-(a) and 8-(b), in the heat sink with fins comprising the cylindrical base member 2 and a plurality of fins 3 which are inserted into a plurality of grooves formed in the side face of the cylindrical base member and then both sides of each of the grooves are plastic-deformed to joint the fins in the base member, a part of the central portion of the base member 2 is cut out to form a hollow portion 13.

When a core of the fan is installed in thus formed hollow portion 13, an integrally formed heat sink and fan may be obtained. Furthermore, when the part of the central portion of the base member as explained with reference to FIG. 3 is cut out to form the hollow portion 13, and the core of the fan is installed within the hollow portion, the integrally formed heat sink and fan can be obtained. As a result, it is possible to downsize the heat sink with fins and to reduce the number of the components.

The above-mentioned plastic deformation may be carried out continuously or discontinuously along the grooves. When the bottom portion in the plastic-deformed portion is formed widely by the pressing jig, the fins can be mechanically firmly crimped. For example, a tapered recessed portion having a substantially trapezoidal cross section comprising a flat bottom face and slanted side faces is formed by plastic deformation to crimp and joint the fin within the groove. More specifically, since the amount of the plastic deformation is large, the slanted faces are pressed to the fin so that the fin is pressed even in its deeper portion within the groove.

For the pressing jig, usual high strength material such as steel may be used. For the base member and the fins, any material having excellent heat transfer property such as copper or aluminum may be used. Since the portion between the fins is pressed by a crimp-edge, a hard material such as copper may be plastic-deformed and manufactured in the same equipment as for aluminum, and furthermore, the fins as a whole are firmly fixed to the base member to improve reliability. The shape of the crimp-edge may be selected within the above-mentioned various kinds. A single piece of the crimp-edge is used to plastic-deform the portion between the fins one at a time, or a plurality of crimp-edges may be used to plastic-deform the respective portions between fins at once. Furthermore, instead of moving the crimp-edge, the crimp-edge may be fixed and the base member is moved against the fixed crimp-edge to plastic-deform. The shape of the crimp-edge may be changed according to kind of the material, the hardness and the size thereof.

As described above, in the heat sink with fins of the invention, since the fins are inserted into the grooves formed in the side face of the cylindrical base member, and the both sides of each of the grooves are plastic-deformed to joint the fins in the base member, the air flow from the fan can be effectively made use of, thus enabling to obtain the heat sink excellent in heat dissipating efficiency.

1. A heat sink with fins comprising a pillar-shaped base member, and a plurality of fins which are inserted into a plurality of grooves formed in a side face of said base member and then both sides of each of said grooves are plastic-deformed to joint said fins in said base member.

2. The heat sink with fins as claimed in claim 1, wherein said fin comprises a flat plate fin, and a plurality of said fins are inserted into each of said grooves.

3. The heat sink with fins as claimed in claim 2, wherein said pillar-shaped base member comprises a truncated cone-shaped base member.

4. The heat sink with fins as claimed in claim 2, wherein said pillar-shaped base member comprises a cylindrical base member.

5. The heat sink with fins as claimed in claim 2, wherein said pillar-shaped base member comprises a polygonal pillar-shaped base member.

6. The heat sink with fins as claimed in claim 2, wherein said pillar-shaped base member comprises a pipe-shaped base member.

7. The heat sink with fins as claimed in claim 4, wherein each of said grooves is formed to be inclined so as to have a specific angle to a longitudinal axis of said base member.

8. The heat sink with fins as claimed in claim 4, wherein each of said grooves is formed to be inclined so as to have a specific angle to a respective normal line on a surface of said base member.

9. The heat sink with fins as claimed in claim 4, wherein at least one slit is formed in a portion of said base member along an axis direction thereof.

10. The heat sink with fins as claimed in claim 4, which further comprises a cover portion to cover at least part of an outer peripheral portion formed by connecting outer side ends of respective said plurality of fins jointed in said base member.

11. The heat sink with fins as claimed in claim 4, wherein at least a part of a central portion of said base member is cut out along a longitudinal axis thereof.

12. A method for manufacturing a heat sink with fins comprising the steps of:
preparing a pillar-shaped base member and a plurality of fins;
forming a plurality of grooves in a side face of said base member, each of which has a prescribed constant angle to a respective normal lines in the surface of the base member;
inserting the plurality of fins into the respective grooves; and
plastic-deforming respective portions of the surface of the base member forming obtuse angle to the fins to joint the fins to the base member.

13. A method for manufacturing a heat sink with fins comprising the steps of:
preparing a pillar-shaped base member and a plurality of fins;
forming a plurality of grooves in a side face of said base member;
inserting the plurality of fins into the respective grooves;
plastic-deforming respective side portions of the fins in the surface of the base member by moving a pressing jig toward an axis of the base member to joint the fins to the base member; and
moving the pressing jig away from the axis of the base member.

14. A method for manufacturing a heat sink with fins comprising the steps of:
preparing a pillar-shaped base member in which a part of a central portion is cut out along a longitudinal axis thereof and a plurality of fins;
forming a plurality of grooves in a side face of said base member;
inserting the plurality of fins into the respective grooves;
placing a deform-preventing jig in a respective space between fins;
inserting a pressing jig in the cutout central portion; and
expanding the pressing jig outwardly to deform the base member to joint the fins to the base member.

15. The method as claimed in claim 14, wherein said pressing jig is inserted through a sheet in the cutout central portion.

16. The method as claimed in claim 14, wherein said deform-preventing jig is fixed on the base member when pressed, and said deform-preventing jig is released after finishing the pressing.

17. The method as claimed in claim 14, wherein said pressing jig inserted in the cutout central portion changes in an outer diameter to deform the base member.

18. A method for manufacturing a heat sink with fins comprising the steps of:
preparing a truncated cone-shaped base member and a plurality of fins;
forming a plurality of grooves in a side face of said base member;
inserting the plurality of fins into the respective grooves;
plastic-deforming respective side portions of the fins in the surface of the base member by moving a pressing jig having a stepped cutting portion in parallel to an axis of the base member to joint the fins to the base member.
